(19) United States
(12) Patent Application Publication
(10) Pub. No.: US 2026/0018913 A1
(43) Pub. Date: Jan. 15, 2026

(54) CHARGING DEVICE

(71) Applicant: Delta Electronics, Inc., Taoyuan City (TW)

(72) Inventors: Feng-Sheng CHEN, Taoyuan City (TW); Ting-Yun LU, Taoyuan City (TW); Jing Yuan CHENG, Taoyuan City (TW)

(21) Appl. No.: 19/013,190

(22) Filed: Jan. 8, 2025

(30) Foreign Application Priority Data
Jul. 9, 2024 (CN) 202421610452.7

(51) Int. Cl. H02J 7/00; H05K 7/20

(52) U.S. Cl. CPC H02J 7/0042; H05K 7/20145

(57) ABSTRACT

A charging device for charging a battery is provided, including a first housing, a channel, a fan, an electronic member, and a second housing. The first housing has an inner space. The channel passes through the first housing, and the wall of the channel separates the channel from the inner space. The fan is disposed in the channel. The electronic member is disposed in the inner space and is in contact with the wall of the channel. The second housing has an accommodating space. The accommodating space is configured to receive the battery and communicates with the channel.

### CROSS REFERENCE TO RELATED APPLICATIONS

The present application claims priority of China Utility Model application No. 202421610452.7, filed Jul. 9, 2024, which is incorporated by reference herein in its entirety.

### BACKGROUND OF THE INVENTION

### Field of the Invention

The application relates in general to a charging device, and in particular, to a charging device that has high heat dissipation and is waterproof at the same time.

### Description of the Related Art

Advanced technology has led to the development of various electronic devices for use in daily life. Portable electronic devices need batteries to supply power. When battery power runs out, this battery should be put into a specific charger, to provide power to the battery.

However, when the charger charges the battery, the battery and the charger generate heat. If the temperature is too high, it may cause a failure of the battery to be charged. Therefore, how to address the aforementioned problem has become an important issue.

### BRIEF SUMMARY OF INVENTION

To address the deficiencies of conventional products, an embodiment of the invention provides a charging device, configured to charge a battery. The charging device includes a first housing, a channel, a fan, an electronic member, and a second housing. The first housing has an inner space. The channel passes through the first housing, and the wall of the channel separates the channel from the inner space. The fan is disposed in the channel. The electronic member is disposed in the inner space and is in contact with the wall of the channel. The second housing has an accommodating space, wherein the accommodating space is configured to receive the battery and communicates with the channel.

In some embodiments, the first housing has a wind hole, and the wind hole communicates with the channel and the external environment.

In some embodiments, the second housing has an opening, and the accommodating space communicates with the external environment via the opening.

In some embodiments, the fan drives the air in the external environment to enter the accommodating space via the opening, and after the air flows through the channel, the air leaves the charging device via the wind hole.

In some embodiments, the charging device further comprises a through hole penetrating the first housing and the second housing to allow the accommodating space to communicate with the channel, and the position of the through hole corresponds to the position of the opening.

In some embodiments, the second housing separates the accommodating space from the external environment.

In some embodiments, the fan drives the air in the external environment to enter the channel via the wind hole, and after the air flows through the channel, the air enters the accommodating space.

In some embodiments, the first housing comprises a top wall and a lateral wall, the top wall is connected to the lateral wall, the wind hole is formed on the lateral wall, and the second housing is disposed on the top wall.

In some embodiments, the charging device further comprises a through hole penetrating the first housing and the second housing to allow the accommodating space to communicate with the channel, and the fan is adjacent to the through hole.

In some embodiments, the wall of the channel has a first section and a second section, the first section is spaced away from the electronic member, the second section is in contact with the electronic member, and an obtuse angle is formed between the first section and the second section.

### BRIEF DESCRIPTION OF DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic diagram of a charging device according to an embodiment of the invention;

FIG. 2 is a cross-sectional view along line A-A in FIG. 1;

FIG. 3 is a schematic diagram represents that the air in the external environment flows through the accommodating space, the through hole, the channel, and the wind hole in sequence according to an embodiment of the invention;

FIG. 4 is a schematic diagram of a charging device according to another embodiment of the invention, wherein the fan drives the air in the external environment to flow through the wind hole, the channel, the through hole, and the accommodating space in sequence;

FIG. 5 is a schematic diagram of a charging device according to another embodiment of the invention; and

FIG. 6 is a schematic diagram of a charging device according to another embodiment of the invention.

### DETAILED DESCRIPTION OF INVENTION

The making and using of the embodiments of the charging device are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

The following disclosure provides many different embodiments, or examples, for implementing different features of the subject matter provided. Specific examples of solutions and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

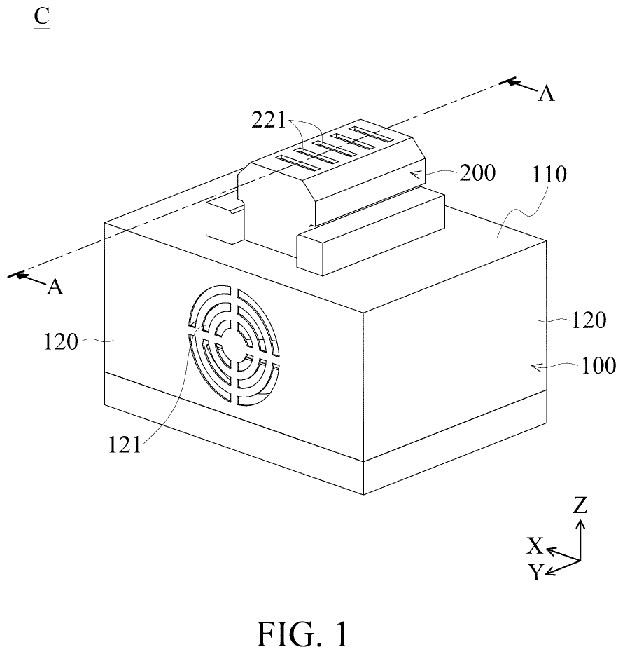

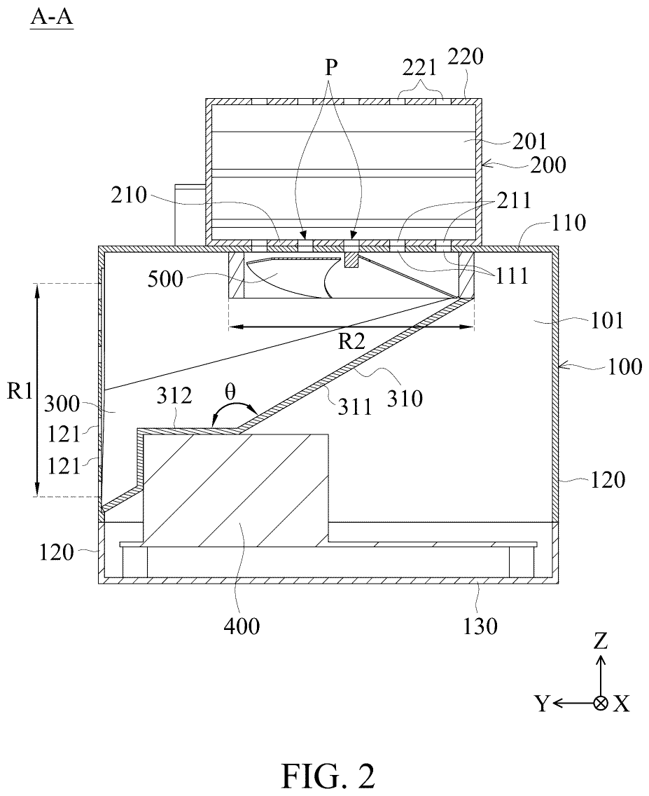

FIG. 1 is a schematic diagram of a charging device C according to an embodiment of the invention, and FIG. 2 is a cross-sectional view along line A-A in FIG. 1. The charging device C can be configured to provide power to one or more power storing members to store the power therein. For example, the power storing member can be a battery (such as a nickel-cadmium battery, a nickel-metal hydride battery, a lithium-ion battery, a lithium polymer battery, and/or lead-acid battery), but it is not limited thereto.

As shown in FIG. 1 and FIG. 2, the charging device C primarily includes a first housing 100, a second housing 200, a channel 300, one or more electronic members 400, and a fan 500. The first housing 100 includes a top wall 110, a plurality of lateral walls 120, and a bottom wall 130. The top wall 110 and the bottom wall 130 is situated at the opposite sides of the first housing 100, and the lateral walls 120 is connected to the top wall 110 and the bottom wall 130. Therefore, the inner of the first housing 100 forms an inner space 101 that is surrounded by the top wall 110, the lateral walls 120, and the bottom wall 130. At least one opening 111 is formed on the top wall 110, and at least one wind hole 121 is formed on one of the lateral walls 120.

The second housing 200 is disposed on the top wall 110 of the first housing 100, and includes an accommodating space 201. When the user wants to use the charging device C to charge the power storing member, the power storing member can be accommodated in the accommodating space 201 of the second housing 200. The shape of the inner surface of the second housing 200 facing the accommodating space 201 matches the shape of the power storing member that is to be charged. Thus, when the user places the power storing member into the accommodating space 201, the power storing member can be directly positioned. At least one opening 211 can be formed on the wall 210 of the second housing 200, the wall 210 is in contact with the first housing 100, and the opening 211 is aligned with the opening 111 on the top wall 110 of the first housing 100. Therefore, at least one through hole P penetrating the first housing 100 and the second housing 200 can be formed. Moreover, at least one opening 221 can be formed on the wall 220 of the second housing 200, the wall 220 faces away the first housing 100, and the accommodating space 201 communicates with the external environment via the opening 221. In this embodiment, the position of the through hole P corresponds to the position of the opening 221.

The channel 300 passes through the first housing 100. Specifically, the wall 310 of the channel 300 can separate the channel 300 from the inner space 101 of the first housing 100. In other words, the channel 300 is not communicated with the inner space 101 of the first housing 100. The channel can entirely cover the opening 111 on the top wall 110 and the wind hole 121 on the lateral wall 120. Therefore, the through hole P formed by the opening 111 and the opening 211 allows the channel 300 to communicate with the accommodating space 201, and the wind hole 121 allows the channel 300 to communicate with the external environment.

The electronic member 400 can be accommodated in the inner space 101 of the first housing 100, and can be in contact with the wall 310 of the channel 300. The shape of the wall 310 of the channel 300 can match the shape of the electronic member 400. For example, as shown in FIG. 2, the wall 310 of the channel 300 can include a first section 311 and a second section 312. The first section 311 is spaced away from the electronic device 400, and the second section 312 is in contact with the electronic device 400. Since the shape of the wall 310 of the channel 300 matches the shape of the electronic device 400, an obtuse angle θ can be formed between the first section 311 and the second section 312. In this embodiment, the second section 312 can be substantially perpendicular to the lateral wall 120 of the first housing 100 having the wind hole 121. The electronic device 400 can include a power supply, a processor, a circuit board, a resistor, a capacitor, a wire, and/or a wireless charging coil, but it is not limited thereto.

The fan 500 is disposed in the channel 300 and adjacent to the through hole P. In this embodiment, the arrangement range R1 of the wind holes 121 is greater than the projection range R2 of the fan 500 onto the top wall 110. The fan 500 can drive the air to flow, so that the air in the external environment can flow through the channel 300 and the accommodating space 201.

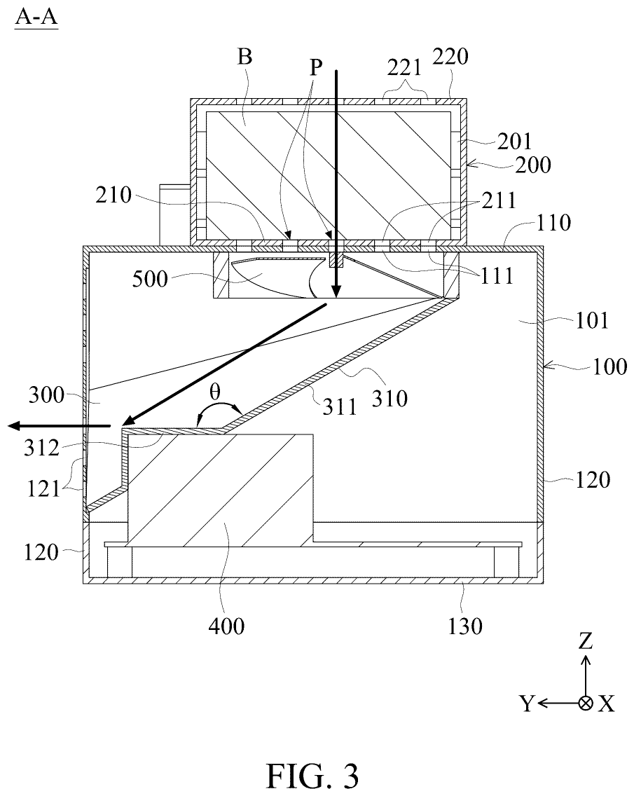

The use of the charging device C is discussed below. As shown in FIG. 3, when the power storing member B is disposed in the accommodating space 201 of the second housing 200, the charging device C can supply power to the power storing member B (for example, supply by the electronic member 400), and the power storing member B and the electronic member 400 may generate the heat. The fan 500 can start to operate and drive the air in the external environment to enter the accommodating space 201 from the opening 221 of the second housing 200. The air can flow through the accommodating space 201, the through hole P, and the channel 300 in sequence, and leave the charging device C via the wind hole 121 of the first housing 100.

Since the air flows through the accommodating space 201 that accommodates the power storing member B, it can bring out the heat generated by the power storing member B. Similarly, since the electronic member 400 is in contact with the wall 310 of the channel 300, the air can also bring out the heat from the electronic member 400. The charging device C of the present disclosure can significantly reduce the temperature of the power storing member B and the electronic member 400, so that the charging efficiency of the charging device C can be effectively enhanced, and the failure caused by overheating can be prevented.

Since the obtuse angle θ is formed between the second section 312 and the first section 311, the air can completely flow through the second section 312 that is in contact with the electronic member 400. Thus, it can be ensured that the air brings out the heat on the second section 312.

Furthermore, since the wall 310 of the channel 300 separates the channel 300 from the inner space 101 of the first housing 100, the charging device C of the present disclosure can reduce the temperature of the electronic member 400 by the air flow and still maintain the sealing of the inner space 101. The foreign object or liquid can be prevented from entering the inner space 101, so that the waterproof of the charging device C can be achieved.

When the temperature of the external environment is low (for example, the temperature is lower than 0° C.), the charging device C can further include a heater (not shown) disposed in the channel 300 or the position adjacent to the wind hole 121. The fan 500 can reversely operate, the air heated by the heater can flow through the channel 300 and the accommodating space 201 in sequence. The electronic member 400 and the power storing member B can be in a constant temperature, so that they will not unable to operate due to the low temperature.

In some embodiments, the temperature of the power storing member B slightly rises during the charging process, the fan 500 can drive the air in the external environment to flow through the wind hole 121, the channel 300, the through hole P, and the accommodating space 201 in sequence and leave the charging device C via the opening 221 of the second housing 200 to reduce the temperature of the power storing member B and the electronic member 400.

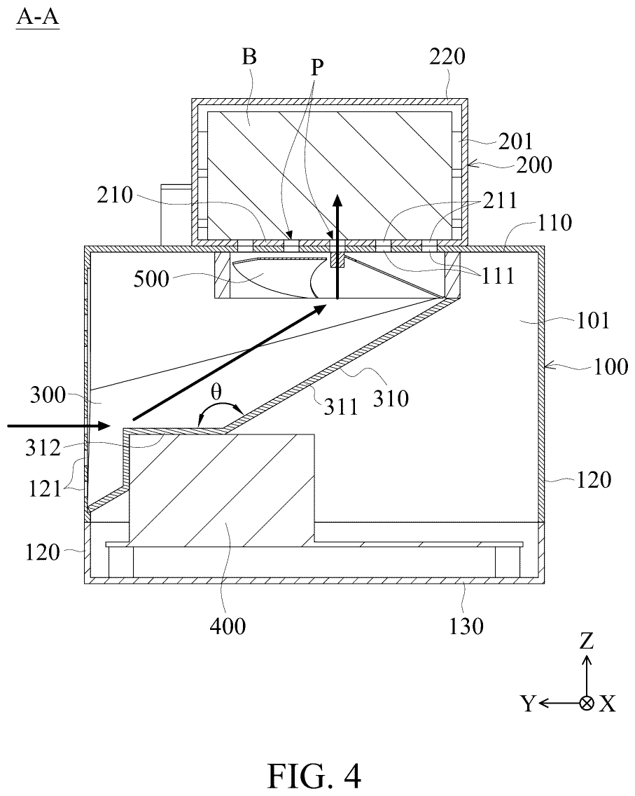

Referring to FIG. 4, in another embodiment, the charging device C primarily includes a first housing 100, a second housing 200, a channel 300, one or more electronics 400, and a fan 500. The arrangements and the structures of the first housing 100, the channel 300, the electronic device 400, and the fan 500 are the same as that in the charging device C shown in FIG. 1, so that the features thereof are not repeated in the interest of brevity.

In this embodiment, the second housing 200 only has at least one opening 211 formed on the wall 210 that is aligned with the opening 111 of the first housing 100. Therefore, the second housing 200 can separate the accommodating space 201 from the external environment, making it difficult for foreign objects or liquids to enter the accommodating space 201, and the probability of the failure of the power storing member B can be reduced.

In this embodiment, the fan 500 drives the air in the external environment to flow into the channel 300 via the wind hole 121. After the air flows through the channel 300 and the through hole P in sequence, the air enters the accommodating space 201.

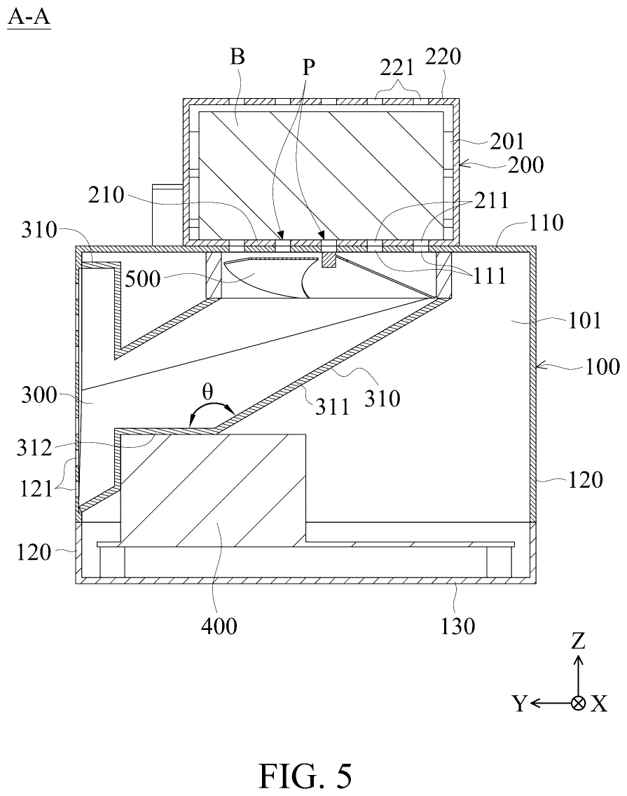

In the aforementioned embodiments, the channel 300 is formed by the wall 310 and the first housing 100, but it is not limited thereto. For example, as shown in FIG. 5, the channel 300 can be formed by the wall 310 surrounding the channel 300.

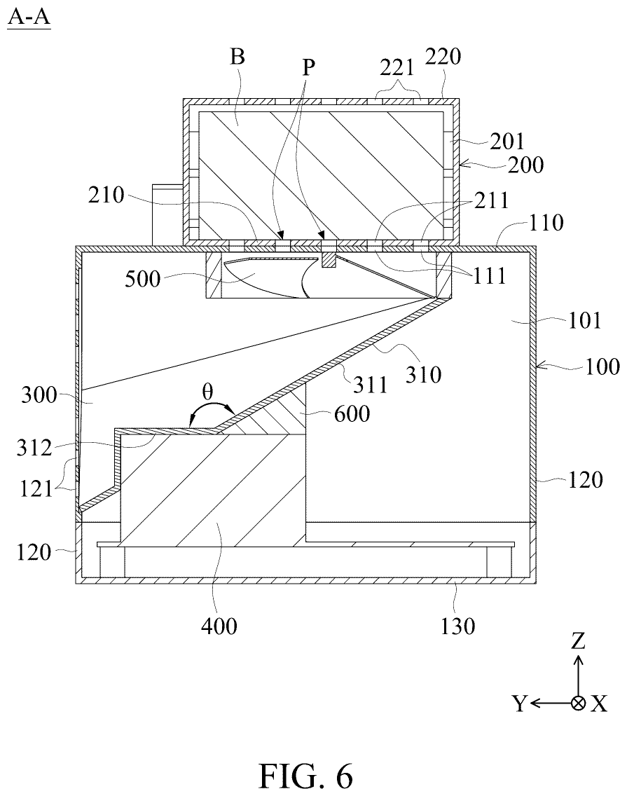

Referring to FIG. 6, in some embodiments, the charging device C further includes a heat conductive member 600. The heat conductive member 600 is disposed between the wall 310 and the electronic member 400 and contacts them, so as to transmit the heat of the electronic member 400 to the wall 310 of the channel 300. Therefore, the charging device C can dissipate the heat more efficiently. In this embodiment, the heat conductive member 600 can disposed between the first section 311 and the electronic member 400 and contacts them. In some embodiments, the heat conductive member 600 can be filled between the second section 312 of the wall 310 and the electronic member 400 and contacts them. For example, the heat conductive member 600 can be the thermal paste or the thermal glue, but it is not limited thereto.

In summary, an embodiment of the disclosure provides a charging device, configured to charge a battery. The charging device includes a first housing, a channel, a fan, an electronic member, and a second housing. The first housing has an inner space. The channel passes through the first housing, and the wall of the channel separates the channel from the inner space. The fan is disposed in the channel. The electronic member is disposed in the inner space and is in contact with the wall of the channel. The second housing has an accommodating space, wherein the accommodating space is configured to receive the battery and communicates with the channel.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A charging device for charging a battery, comprising:
a first housing, having an inner space;
a channel, passing through the first housing, wherein a wall of the channel separates the channel from the inner space;
a fan, disposed in the channel;
an electronic member, disposed in the inner space and contacting the wall of the channel; and
a second housing, having an accommodating space, wherein the accommodating space is configured to receive the battery and communicates with the channel.

2. The charging device as claimed in claim 1, wherein the first housing has a wind hole, and the wind hole communicates with the channel and an external environment.

3. The charging device as claimed in claim 2, wherein the second housing has an opening, and the accommodating space communicates with the external environment via the opening.

4. The charging device as claimed in claim 3, wherein the fan drives an air in the external environment to enter the accommodating space via the opening, flow through the channel, and leave the charging device via the wind hole.

5. The charging device as claimed in claim 3, wherein the charging device further comprises a through hole penetrating the first housing and the second housing to allow the accommodating space to communicate with the channel.

6. The charging device as claimed in claim 2, wherein the second housing separates the accommodating space from the external environment.

7. The charging device as claimed in claim 6, wherein the fan drives an air in the external environment to enter the channel via the wind hole, flow through the channel, and then enter the accommodating space.

8. The charging device as claimed in claim 2, wherein the first housing comprises a top wall and a lateral wall, the top wall is connected to the lateral wall, the wind hole is formed on the lateral wall, and the second housing is disposed on the top wall.

9. The charging device as claimed in claim 1, wherein the charging device further comprises a through hole penetrating the first housing and the second housing to allow the accommodating space to communicate with the channel, and the fan is adjacent to the through hole.

10. The charging device as claimed in claim 1, wherein at least a portion of the electronic member is in contact with the wall via a heat conductive member, and the heat conductive member is disposed between the wall and the electronic member.
